(19) United States
(12) Patent Application Publication
(10) Pub. No.: US 2022/0379491 A1
(43) Pub. Date: Dec. 1, 2022

(54) Management System and Control Method for Management System

(71) Applicant: Hitachi Industrial Products, Ltd., Chiyoda-ku, Tokyo (JP)

(72) Inventor: Akiharu IKEDA, Tokyo (JP)

(21) Appl. No.: 17/642,049

(22) PCT Filed: Apr. 21, 2020
(86) PCT No.: PCT/JP2020/017269

§ 371 Date: Mar. 10, 2022

(30) Foreign Application Priority Data
Sep. 11, 2019 (JP) 2019-165236

(51) Int. Cl. B25J 13/08; B25J 9/16; B65G 1/137

(52) U.S. Cl. CPC B25J 13/089; B25J 9/1612; B25J 9/1687; B25J 9/1664; B65G 1/1375

(57) ABSTRACT

Provided is a management system for managing storage and retrieval of items. The management system includes a transfer robot that includes a drive mechanism and a sensor, the drive mechanism being configured to move a shelf along a transfer route to a region where any one of operations of carrying in an item, carrying out the item, and transferring the item between shelves is enabled to be performed, and place the shelf at a predetermined position, the sensor being configured to detect a position of the transfer robot in a space where the transfer robot is allowed to be moved, a device configured to perform at least either the operation or assistance in the operation, and a first controller configured to generate control data for controlling the device and output the control data to the device, the control data being generated on the basis of an error between a position of the shelf transferred by the transfer robot and a target position on the transfer route, the error being calculated by using the position of the transfer robot detected by the sensor.

### INCORPORATION BY REFERENCE

The present application claims the priority of Japanese Patent Application No. 2019-165236 filed on Sep. 11, 2019, the contents of which are incorporated herein by reference.

### TECHNICAL FIELD

The present invention relates to a system for managing distribution of items.

### BACKGROUND ART

A transfer robot used to transfer loads is referred to as an unmanned carrier or an AGV (Automatic Guided Vehicle). Such transfer robots are widely introduced into facilities such as warehouses, factories, and ports.

Additionally, since customer needs have recently been diversified, an increasing number of warehouses deal with a wide variety of items in small quantities as in the case of warehouses for mail-order services. Due to the properties of items to be managed, much time and high personnel costs are required to search for and load items. Thus, warehouses for mail-order services require more highly automated operations of distributing items within the facility than that in warehouses dealing with a single type of items in a large quantity.

For example, there is a known system which performs automated warehouse management by using a transfer robot that transfers a shelf housing items and an arm robot that performs either an operation of carrying items onto a shelf or an operation of carrying out items from a shelf. There is also a known system in which devices that assist in operations, such as a laser irradiator that points at a target item and a display device that displays projection mapping indicating instructions for operations, are provided and in which, instead of the arm robot, a person performs operations.

In a management system which includes an arm robot, it is required to accurately determine the position of an item when the arm robot carries out the item from a shelf. Additionally, to allow devices that assist in operations to function correctly, the positions of items need to be accurately determined. Thus, according to a work plan, the management system generates control data for each device with consideration of the positions of items and controls the device on the basis of the control data.

However, in a case where the transfer robot transfers a shelf to a work area of the arm robot or a human operator, the transferred shelf may be misaligned with respect to a target position. Thus, the management system for a warehouse needs to control devices with consideration of a misalignment.

A technology described in Patent Document 1 is known as a technology for detecting the position of an item to be gripped. Patent Document 1 discloses “a transfer robot that includes a substrate detection sensor 5 for detecting whether or not a substrate attached to the vicinity of a tip of a hand 4 is present, a movement mechanism 11 for moving the position of the hand, an operation control section 12 for controlling the position of the hand and a movement speed, and a substrate edge position analysis section 13 for calculating the edge position of the substrate.”

### PRIOR ART DOCUMENT

### Patent Document

Patent Document 1: JP-2011-228616-A

### SUMMARY OF INVENTION

### Problems to be Solved by the Invention

In a case where the technology described in Patent Document 1 is applied to the warehouse management system, a sensor configured to detect whether or not an item is present needs to be installed in the arm robot, a shelf, or the like. This disadvantageously increases the costs of the entire system. Additionally, depending on a system environment, the sensor may fail to be installed in the arm robot or the shelf.

The present invention provides a technology for feeding back a misalignment of a shelf transferred by a transfer robot, to a device that performs an operation itself or that assists in the operation.

### Means for Solving the Problems

A typical example of the present invention disclosed herein is described below. Specifically, there is provided a management system for managing storage and retrieval of items. The management system includes a transfer robot, a device, and a first controller. The transfer robot includes a drive mechanism and a sensor. The drive mechanism moves a shelf along a transfer route to a region where any one of operations of carrying in an item, carrying out the item, and transferring the item between shelves is enabled to be performed, and places the shelf at a predetermined position. The sensor detects a position of the transfer robot in a space where the transfer robot is allowed to be moved. The device performs at least either the operation or assistance in the operation. The first controller generates control data for controlling the device and output the control data to the device. The control data is generated on the basis of an error between a position of the shelf transferred by the transfer robot and a target position on the transfer route, the error being calculated by using the position of the transfer robot detected by the sensor.

### Advantages of the Invention

According to the present invention, a misalignment of the shelf transferred by the transfer robot can be fed back to the device that performs the operation itself or that assists in the operation, with costs prevented from being increased. Objects, configurations, and effects other than those described above will be clarified in the following description of embodiments.

### BRIEF DESCRIPTION OF THE DRAWINGS

FIG. 1 is a diagram depicting an example of a configuration of a warehouse management system according to a first embodiment.

FIG. 2 is a perspective view depicting an example of a warehouse according to the first embodiment.

FIG. 3 is a plan view depicting an example of the warehouse according to the first embodiment.

FIG. 4 is a diagram depicting specific operating states of an arm robot and a carrier according to the first embodiment.

FIG. 5 is a diagram depicting an example of a misalignment of a shelf transferred by the carrier according to the first embodiment.

FIG. 6 is a flowchart illustrating an example of processing executed by a robot controller according to the first embodiment.

### MODES FOR CARRYING OUT THE INVENTION

Embodiments of the present invention will be described below by using the drawings. However, the present invention should not be restrictively interpreted in the contents of the embodiments described below. It would easily be understood by a person skilled in the art that a specific configuration of the present invention can be changed without departing from the spirit and scope of the present invention.

In the configuration of the present invention described below, identical or similar components or functions are denoted by identical reference signs, and duplicate descriptions are omitted.

The expressions “first,” “second,” “third,” and the like in the present specification and the like are used to identify components and are not necessarily limit the number or order of the components.

For easy understanding of the invention, the positions, sizes, shapes, ranges, and the like of components depicted in the drawings and the like may not represent the actual positions, sizes, shapes, ranges, and the like. Thus, the present invention is not limited to the positions, sizes, shapes, ranges, or the like disclosed in the drawings or the like.

### First Embodiment

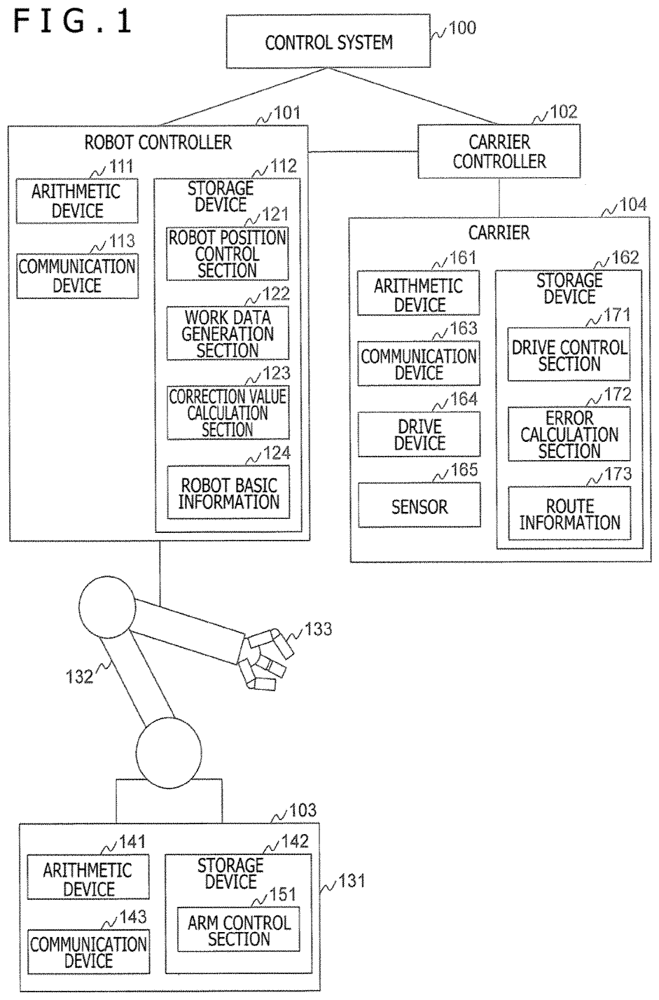

FIG. 1 is a diagram depicting an example of a configuration of a warehouse management system according to a first embodiment.

The warehouse management system includes a control system 100, a robot controller 101, a carrier controller 102, an arm robot 103, and a carrier 104.

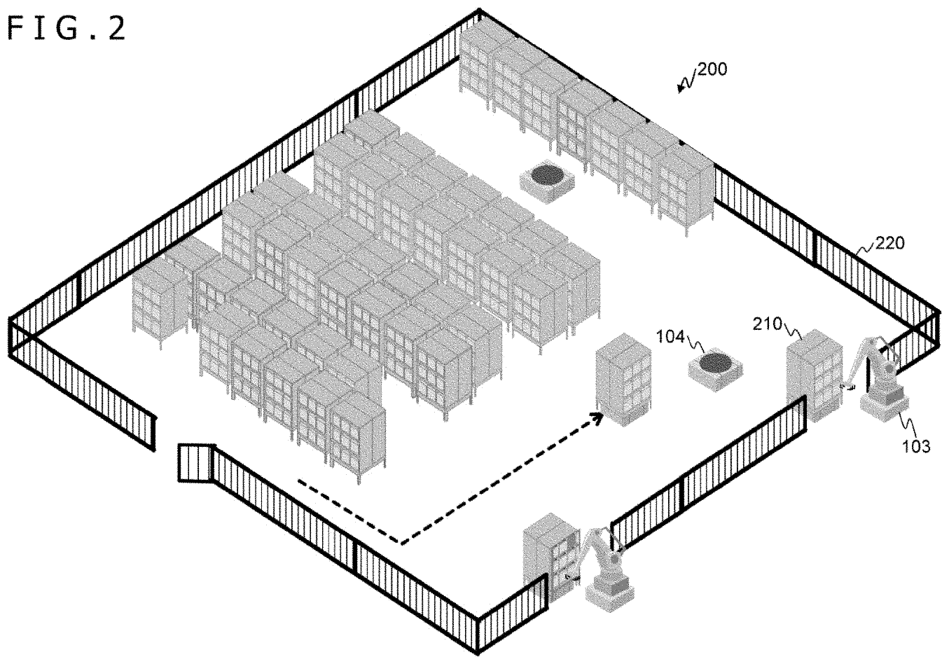

The arm robot 103 and the carrier 104 are disposed in a warehouse 200 (see FIG. 2) in which at least any one of operations of carrying in items, carrying out items, and transferring items between shelves is performed. The control system 100, the robot controller 101, and the carrier controller 102 may be disposed in the warehouse 200 or at a location different from the warehouse 200.

The control system 100 is connected to the robot controller 101 and the carrier controller 102 via a network. The robot controller 101 and the carrier controller 102 are connected together via the network. The robot controller 101 is connected to the arm robot 103 via the network. Additionally, the carrier controller 102 is connected to the carrier 104 via the network.

The network includes, for example, a LAN (Local Area Network), a WAN (Wide Area Network), and the like. A network connection may be established in either a wired or wireless manner.

Note that the number of the robot controllers 101, the number of the carrier controllers 102, the number of the arm robots 103, and the number of the carriers 104, which are included in the warehouse management system, may each be two or more.

The control system 100 controls the entire warehouse management system. The control system 100 includes at least one computer (not illustrated). The control system 100 generates data for giving instructions for operations using the arm robot 103 and transfer of a shelf 210 (see FIG. 2) using the carrier 104, on the basis of a work plan. The instructions related to the operations of the arm robot 103 include information regarding the order of the operations, constraints on the operations, the contents of the operations, and the like.

The robot controller 101 controls the arm robot 103. The robot controller 101 includes an arithmetic device 111, a storage device 112, and a communication device 113.

The arithmetic device 111 includes a processor, a GPU, an FPGA, and the like, and executes programs stored in the storage device 112. The arithmetic device 111 executes processing according to a program to operate as a functional section that implements a specific function. In the description below, in a case where description of processing is using a functional section as a subject of a sentence, the arithmetic device 111 executes the program that implements the functional section.

The storage device 112 is a memory or the like, and stores programs to be executed by the arithmetic device 111 and information to be used by the programs. The storage device 112 includes a work area that is temporarily used by the programs.

The communication device 113 communicates with an external device via the network. The communication device 113 is, for example, a network interface.

The storage device 112 stores programs that implement a robot position control section 121, a work data generation section 122, and a correction value calculation section 123, and also stores robot basic information 124.

The robot basic information 124 stores information related to the size of the arm robot 103, the operation range of the arm robot 103, layout dimensions, and the like.

The work data generation section 122 generates teaching data for controlling the arm robot 103. Specifically, on the basis of the robot basic information 124 and information that is included in an instruction received from the control system 100, the work data generation section 122 calculates three-dimensional coordinates of the arm robot 103. Then, on the basis of the calculated three-dimensional coordinates, the work data generation section 122 generates teaching data for causing the arm robot 103 to perform a predetermined operation. The teaching data includes values of various parameters for controlling the arm robot 103.

The correction value calculation section 123 calculates errors in the positions of the shelf 210 and an item storage container 400 which are involved in a misalignment of stop position of the carrier 104. Further, on the basis of the errors, the correction value calculation section 123 calculates a correction value for correcting the teaching data.

The robot position control section 121 controls the arm robot 103 on the basis of the teaching data generated by the work data generation section 122. In a case where a correction value calculated by the correction value calculation section 123 is received, the robot position control section 121 corrects the teaching data by using the correction value, and controls the arm robot 103 on the basis of the corrected teaching data.

Note that the work data generation section 122 may generate, on the basis of the robot basic information 124, teaching data for controlling the arm robot 103 under various situations and store the teaching data in a teaching database. In a case of receiving an instruction from the control system 100, the robot position control section 121 acquires teaching data from the teaching database, acquires a correction value from the correction value calculation section 123, and corrects the teaching data on the basis of the correction value.

Note that, as for the functional sections of the robot controller 101, a plurality of functional sections may be integrated into one functional section, or one functional section may be divided into a plurality of functional sections on a functional basis.

The carrier controller 102 controls the carrier 104. The hardware configuration of the carrier controller 102 is identical to the hardware configuration of the robot controller 101, and description of the hardware configuration of the carrier controller 102 is omitted. The carrier controller 102 generates route information 173 for controlling the carrier 104, on the basis of an instruction from the control system 100.

The arm robot 103 includes a robot main body 131, an arm 132, and a hand 133.

The arm 132 is a single-joint arm or a multi-joint arm and has an end attached to the hand 133. The hand 133 includes multiple fingers to grip an item or the item storage container 400. The arm 132 and the hand 133 each include a drive device such as a motor.

The robot main body 131 controls the entire arm robot 103. The robot main body 131 includes an arithmetic device 141, a storage device 142, and a communication device 143. The arithmetic device 141, the storage device 142, and the communication device 143 have similar hardware configurations to those of the arithmetic device 111, the storage device 112, and the communication device 113.

The storage device 142 stores a program that implements an arm control section 151. The arm control section 151 controls the arm 132 and the hand 133 on the basis of the teaching data transmitted by the robot controller 101.

The carrier 104 includes an arithmetic device 161, a storage device 162, a communication device 163, a drive device 164, and a sensor 165. The arithmetic device 161, the storage device 162, and the communication device 163 have similar hardware configurations to those of the arithmetic device 111, the storage device 112, and the communication device 113.

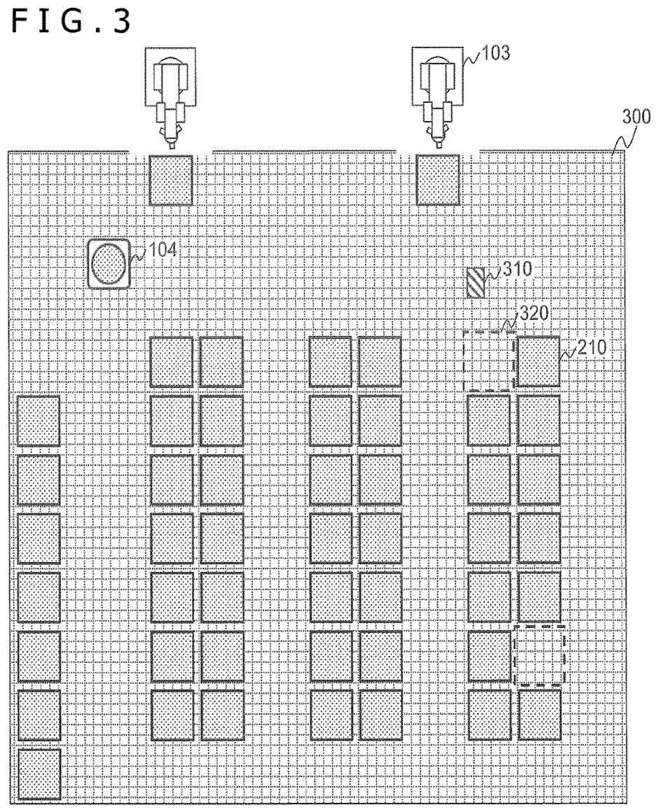

The drive device 164 is a device that is used to transfer the shelf 210, such as a motor and drive wheels. The sensor 165 is a device that detects the state of the surroundings of the carrier 104 and that identifies the position of the carrier 104 in a space where the carrier 104 moves. The sensor 165 is, for example, a camera and reads a marker 310 (see FIG. 3) placed on a floor surface 300 (see FIG. 3). Additionally, the sensor 165 may be a sensor that measures a distance between the carrier 104 and a surrounding object (for example, a laser distance sensor). The carrier 104 identifies its own position on the basis of the marker 310 read by using the sensor 165, and also identifies its own position by matching, against a map, a geometric data of the surrounding environment measured by using the sensor 165.

The storage device 162 stores programs that implement a drive control section 171 and an error calculation section 172, and also stores route information 173. Note that the storage device 162 may store map information for managing a space where the carrier 104 can move.

The route information 173 is information regarding a transfer route along which the shelf 210 is transferred. The drive control section 171 transfers the shelf 210 on the basis of the route information 173. The transfer route in the present specification means a route from a position where the shelf 210 has been placed (start point) to a position where the shelf 210 is to be placed (end point). The error calculation section 172 calculates a misalignment of the stop position of the carrier 104.

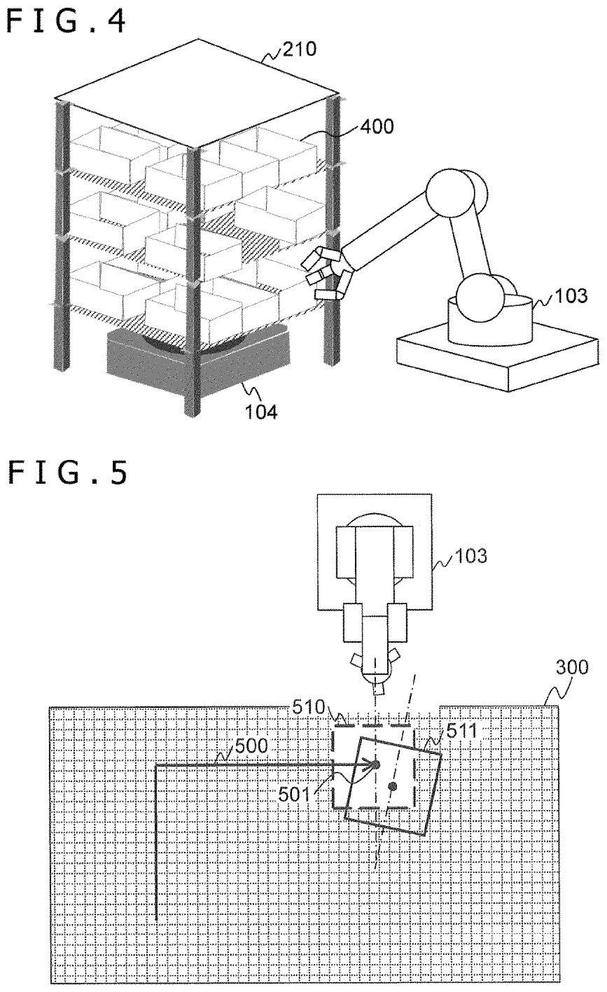

FIG. 2 is a perspective view depicting an example of the warehouse 200 according to the first embodiment. FIG. 3 is a plan view depicting an example of the warehouse 200 according to the first embodiment. FIG. 4 is a diagram depicting specific operating states of the arm robot 103 and the carrier 104 according to the first embodiment.

The warehouse 200 includes a zone defined by a wall 220 such as wire mesh. In FIG. 2, it is assumed that one zone is present in the warehouse 200. The carrier 104 and the shelves 210 are disposed in the one zone.

A plurality of shelves 210 constitute a “shelf block.” In the example depicted in FIG. 2 and FIG. 3, there are three “shelf blocks” each of which includes two rows and seven columns, and there is also one “shelf block” which includes one row and seven columns. Note that the number of the shelves 210 constituting the “shelf block” and the shape of the “shelf block” are optional.

The carrier 104 can take a target shelf 210 out of the “shelf block” and move the target shelf 210 to a destination. Additionally, the carrier 104 can move the shelf 210 from any position to the original position. As depicted in FIG. 4, the carrier 104 moves into a gap below the shelf 210, holds the shelf 210 thereon at a predetermined position, and then starts moving.

The arm robot 103 is disposed in a work area adjacent to the zone. The arm robot 103 is fixed at any position in the work area. As depicted in FIG. 4, the arm robot 103 grips an item housed in the item storage container 400 in the shelf 210. The item storage container 400 is a container for housing an item. Note that the shelf 210 may house items themselves.

The floor surface 300 of the warehouse 200 forming the zone is provided with the marker 310 that indicates an absolute position on the floor surface 300. Although only one marker 310 is placed on the floor surface 300 in FIG. 3, a plurality of markers 310 are placed in practice.

The carrier 104 is equipped with a camera for detecting the marker 310. The camera is an example of the sensor 165.

FIG. 5 is a diagram depicting an example of a misalignment of the shelf 210 transferred by the carrier 104 according to the first embodiment.

To place the shelf 210 at a target position 501 which is an end point of the transfer route, the carrier 104 moves the shelf 210 along the transfer route 500. At this time, it is preferable that the shelf 210 is placed in an arrangement state 510. However, in some cases, depending on the control accuracy, the condition of the floor surface 300, and the like, the actual shelf 210 may be placed in an arrangement state 511.

The misalignment of the shelf 210 includes a misalignment on a plane (coordinate misalignment) and a misorientation of the shelf 210 with respect to the arm robot 103 (angular misalignment).

After the carrier 104 arrives at the target position 501, the drive control section 171 of the carrier 104 identifies the stop position on the basis of the marker 310 detected by using the sensor 165. Additionally, the error calculation section 172 of the carrier 104 calculates the coordinate misalignment and angular misalignment of the shelf 210 on the basis of the current position of the carrier 104 and the target position 501 on the transfer route 500. The error calculation section 172 of the carrier 104 transmits, as position error information, the calculated coordinate misalignment and angular misalignment of the shelf 210 to the robot controller 101 via the carrier controller 102.

Note that, in a case where the shelf 210 has no coordinate misalignment or angular misalignment, the error calculation section 172 transmits, to the robot controller 101, position error information indicating non-occurrence of a coordinate misalignment or an angular misalignment.

Note that the carrier controller 102 may include the error calculation section 172. In this case, the drive control section 171 transmits information regarding the stop position to the carrier controller 102.

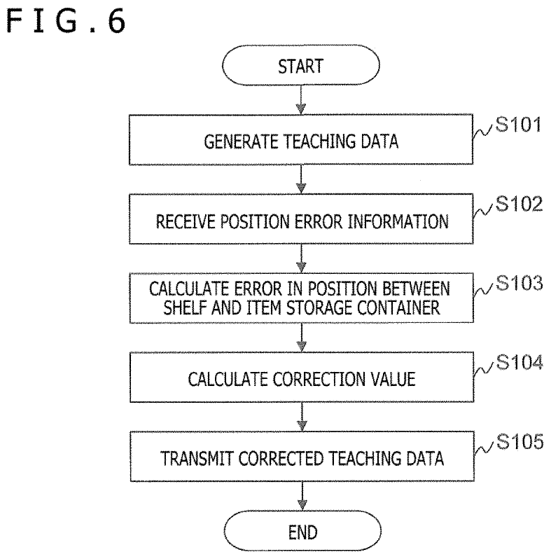

FIG. 6 is a flowchart illustrating an example of processing executed by the robot controller 101 according to the first embodiment.

In a case of receiving an instruction from the control system 100, the robot controller 101 executes processing described below.

The work data generation section 122 of the robot controller 101 generates teaching data (step S101). The robot controller 101 transitions to and stays in a wait state for a certain period of time in order to receive position error information.

Note that, in a case where there is the teaching database, the robot position control section 121 acquires teaching data from the teaching database.

Then, in a case of receiving the position error information from the carrier controller 102 (step S102), the correction value calculation section 123 of the robot controller 101 calculates an error in a relative position between the shelf 210 and the arm robot 103 (step S103).

Specifically, the correction value calculation section 123 calculates an error in a position between the arm robot 103 and the shelf 210 and an error in a position between the arm robot 103 and the item storage container 400. The above-described error in the position can be calculated by using, as a reference position, the ideal position (target position 501) of the shelf 210 transferred along the transfer route 500.

Then, the correction value calculation section 123 of the robot controller 101 calculates a correction value on the basis of the teaching data and the error in the relative position (step S104). In this regard, a correction value for each of the parameters included in the teaching data is calculated.

Then, the robot position control section 121 of the robot controller 101 corrects the teaching data on the basis of the correction values, and transmits the corrected teaching data to the arm robot 103 (step S105). Subsequently, the robot controller 101 ends the processing.

According to the first embodiment, the misalignment of the shelf 210 transferred by the carrier 104 can be fed back to the control of the arm robot 103 that performs the operation. The position of an item (item storage container 400) can correctly be determined without sensor or a camera installed in the arm robot 103. This allows implementation of automatic management of storage and retrieval of items while suppressing operational errors.

### Modified Example 1

In the above description, the arm robot 103 is fixed to the work area. The arm robot 103 may be installed in such a manner as to be movable in three-dimensional directions.

### Modified Example 2

The robot controller 101 calculates the coordinate misalignment and the angular misalignment on the basis of the position of the carrier 104 having arrived at the target position 501. However, the present invention is not limited to the configuration. First, any point on the transfer route 500 is set as a measurement point. The robot controller 101 may calculate the coordinate misalignment and the angular misalignment on the basis of the position of the carrier 104 when the carrier 104 passes through the measurement point on the transfer route 500. This enables a reduction in processing time required to correct the teaching data.

### Modified Example 3

The shelf 210 may be provided with a marker for detecting a placement position. The carrier 104 is equipped with the sensor 165 that detects the marker. On the basis of the position of the marker detected by the carrier 104, the carrier controller 102 calculates the misalignment (coordinate misalignment and angular misalignment) between the ideal placement position of the shelf 210 and the actual placement position of the shelf 210. The carrier controller 102 transmits, as position error information, the error in the stop position of the carrier 104 and the error in the placement position. This allows the teaching data to be corrected with higher accuracy.

### Modified Example 4

The work area or the arm robot 103 can be provided with a sensor for measuring the position of an item, and a value measured by the sensor can be added to the teaching data, thereby improving the correction accuracy of the teaching data.

### Second Embodiment

In the first embodiment, the misalignment of the shelf transferred by the carrier 104 is fed back to the control of the arm robot 103. A second embodiment differs from the first embodiment in that the misalignment is fed back to devices other than the arm robot 103.

Such a device to which the misalignment is to be fed back performs control related to any one of operations of carrying in items, carrying out items, and transferring items between shelves. Specifically, examples of the device which is the feedback destination include a laser irradiator that points at a work position on the shelf 210, a display device that displays, on the shelf 210, projection mapping indicating operation instructions, and a measurement device that measures the dimensions of items housed in the shelf 210. The robot controller 101 according to the second embodiment is connected to the laser irradiator, the display device, the measurement device, and the like.

The robot controller 101 generates control data for controlling the devices connected to the robot controller 101. Additionally, the robot controller 101 corrects the control data on the basis of the correction values calculated by using the position error information.

According to the second embodiment, the misalignment of the shelf 210 transferred by the carrier 104 can be fed back to the control of the device that assists in any one of the operations of carrying in items, carrying out items, and transferring items between shelves.

Note that the present invention is not limited to the embodiments described above and includes various modifications. Additionally, for example, while the configuration has been described in detail in the abovementioned embodiments to describe the present invention in an easy-to-understand manner, the present invention is not necessarily limited to the configuration including all the described components. Additionally, a part of the configuration of each embodiment can be added to or replaced with another configuration, or can be deleted.

Additionally, a part or the whole of each configuration, function, processing section, processing means, or the like may be implemented by hardware by, for example, being designed with use of an integrated circuit. In addition, the present invention can be realized by a software program code that implements the functions of the embodiment. In this case, a storage medium in which a program code is recorded is provided to a computer, and then, a processor included in the computer reads the program code stored in the storage medium. In this case, the program code itself which is read from the storage medium implements the functions of the embodiment described above, and the program code itself and the storage medium which stores the program code constitute the present invention. The storage medium used to supply such a program code is, for example, a flexible disk, a CD-ROM, a DVD-ROM, a hard disk, an SSD (Solid State Drive), an optical disc, a magnetic-optical disc, a CD-R, a magnetic tape, a nonvolatile memory card, a ROM, or the like.

Additionally, the program code which implements the functions described in the present embodiment can be implemented by, for example, a wide variety of programs or script languages such as assembler, C/C++, perl, Shell, PHP, Python, and Java (registered trademark).

Further, the software program code which implements the functions of the embodiment may be distributed via the network and stored in the storage means such as the hard disk or a memory in the computer or the storage medium such as a CD-RW or a CD-R. Then, the processor included in the computer may read and execute the program code stored in the storage means or the storage medium.

While control lines and information lines which facilitate to understand the present invention have been described in the embodiments above, not all the control lines and information lines in the product are described herein. All the components may be connected together.

1. A management system for managing storage and retrieval of items, the management system comprising:
a transfer robot that includes a drive mechanism and a sensor, the drive mechanism being configured to move a shelf along a transfer route to a region where any one of operations of carrying in an item, carrying out the item, and transferring the item between shelves is enabled to be performed, and place the shelf at a predetermined position, the sensor being configured to detect a position of the transfer robot in a space where the transfer robot is allowed to be moved;
a device configured to perform at least either the operation or assistance in the operation; and
a first controller configured to generate control data for controlling the device and output the control data to the device, the control data being generated on a basis of an error between a position of the shelf transferred by the transfer robot and a target position on the transfer route, the error being calculated by using the position of the transfer robot detected by the sensor.

2. The management system according to claim 1, wherein
the device is an arm robot that has a grip mechanism for gripping the item,
the first controller includes
work data generation section configured to generate the control data for controlling the arm robot,
robot position control section configured to control the arm robot on a basis of the control data, and
error calculation section configured to calculate an error in a relative position between the shelf and the arm robot during the operation on a basis of the error between the position of the shelf transferred by the transfer robot and the target position, and calculate a correction value on a basis of the error in the relative position, and
the robot position control section corrects the control data on a basis of the correction value calculated by the error calculation section, and outputs the corrected control data to the arm robot.

3. The management system according to claim 2, further comprising:
a second controller configured to control the transfer robot, wherein
the second controller
acquires, from the transfer robot, first position information that indicates a position of the transfer robot,
generates, on a basis of the first position information, first misalignment amount information that indicates a coordinate misalignment and an angular misalignment between the position of the shelf transferred by the transfer robot and the target position, and
transfers the first misalignment amount information to the first controller.

4. The management system according to claim 3, wherein
the second controller
acquires second position information that indicates a placement position of the shelf, from the transfer robot holding the shelf thereon according to a placement reference position,
generates, on a basis of the second position information, second misalignment amount information that indicates a coordinate misalignment and an angular misalignment between the placement position of the shelf and the placement reference position, and
transfers the first misalignment amount information and the second misalignment amount information to the first controller.

5. The management system according to claim 1, wherein
the device is any one of an irradiator configured to point at a work position on the shelf, a display device configured to display, on the shelf, projection mapping that indicates an instruction for the operation, and a measurement device configured to measure dimensions of the item housed in the shelf.

6. A control method for a management system for managing storage and retrieval of items,
the management system including
a transfer robot that includes a drive mechanism and a sensor, the drive mechanism being configured to move a shelf along a transfer route to a region where any one of operations of carrying in an item, carrying out the item, and transferring the item between shelves are enabled to be performed, and place the shelf at a predetermined position, the sensor being configured to detect a position of the transfer robot in a space where the transfer robot is allowed to be moved,
a device configured to perform at least either the operation or assistance in the operation, and
a first controller configured to control the device,
the control method comprising:
a first step of causing the first controller to generate control data for controlling the device, on a basis of an error between a position of the shelf transferred by the transfer robot and a target position on the transfer route, the error being calculated by using the position of the transfer robot detected by the sensor; and
a second step of causing the first controller to output the control data to the device.

7. The control method for the management system according to claim 6, wherein
the device is an arm robot that has a grip mechanism for gripping the item,
the first step includes
a step of causing the first controller to generate the control data for controlling the arm robot,
a step of causing the first controller to calculate an error in a relative position between the shelf and the arm robot during the operation on a basis of the error between the position of the shelf transferred by the transfer robot and the target position, and calculate a correction value on a basis of the error in the relative position, and
a step of causing the first controller to correct the control data on a basis of the correction value, and
the second step includes a step of causing the first controller to output the corrected control data to the arm robot.

8. The control method for the management system according to claim 7, wherein
the management system further includes a second controller configured to control the transfer robot, and
the control method for the management system further includes
a step of causing the second controller to acquire, from the transfer robot, first position information that indicates a position of the transfer robot,
a step of causing the second controller to generate, on a basis of the first position information, first misalignment amount information that indicates a coordinate misalignment and an angular misalignment between the position of the shelf transferred by the transfer robot and the target position, and
a step of causing the second controller to transfer the first misalignment amount information to the first controller.

9. The control method for the management system according to claim 8, further comprising:
a step of causing the second controller to acquire second position information that indicates a placement position of the shelf, from the transfer robot holding the shelf thereon according to a placement reference position;
a step of causing the second controller to generate, on a basis of the second position information, second misalignment amount information that indicates a coordinate misalignment and an angular misalignment between the placement position of the shelf and the placement reference position; and
a step of causing the second controller to transfer the first misalignment amount information and the second misalignment amount information to the first controller.

10. The control method for the management system according to claim 6, wherein
the device is any one of an irradiator configured to point at a work position on the shelf, a display device configured to display, on the shelf, projection mapping that indicates an instruction for the operation, and a measurement device configured to measure dimensions of the item housed in the shelf.
